(19) United States
(12) Patent Application Publication
(10) Pub. No.: US 2007/0215879 A1
(43) Pub. Date: Sep. 20, 2007

(54) Opto-electronic devices exhibiting enhanced efficiency

(75) Inventors: Jie Liu, Niskayuna, NY (US); James Anthony Cella, Clifton Park, NY (US); Larry Neil Lewis, Scotia, NY (US); Anil Raj Duggal, Niskayuna, NY (US); James Lawrence Spivack, Cobleskill, NY (US); Qing Ye, Schenectady, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company, Schenectady, NY (US)

(21) Appl. No.: 11/384,769

(22) Filed: Mar. 20, 2006

(51) Int. Cl. H01L 33/00; C09K 9/00

(52) U.S. Cl. 257/79; 252/583

(57) ABSTRACT

Described herein is an organic opto-electronic device comprising a cathode comprising at least one zero-valent metal; an anode; an opto-electronically active organic material; wherein said cathode is in contact with at least one organic ammonium salt. In certain embodiments, the organic ammonium salt has structure (I) 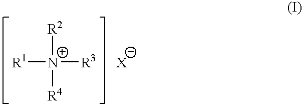
wherein R¹-R⁴ are independently at each occurrence a C₁-C₂₀ aliphatic radical, a C₃-C₂₀ cycloaliphatic radical, or a C₃-C₂₀ aromatic radical is disclosed and wherein X⁺ is selected from the group consisting of monovalent inorganic anions, monovalent organic anions, polyvalent inorganic anions, polyvalent organic anions, and mixtures thereof.

### STATEMENT REGARDING FEDERALLY SPONSORED RESEARCH & DEVELOPMENT

This invention was made with Government support under contract number 70NANB3H3030 awarded by United States National Institute of Standards and Technology. The Government of the United States may have certain rights in the invention.

### BACKGROUND

The present invention relates generally to the field of electro-optics, and more particularly to organic electro-optic devices and methods for making the same. More particularly the invention relates to organic electro-optic devices which operate with enhanced efficiency relative to currently known devices. One class of organic electro-optic devices, organic light-emitting diodes (OLEDs), devices which convert electrical energy into light, has been the object of extensive research and development efforts due to their potential for use in applications such as flat panel displays and general illumination. Another class of organic electro-optic devices, photovoltaic devices, devices which convert light energy into electrical energy, have attracted similar interest. The utility and commercial attractiveness of currently available organic electro-optic devices, such as OLEDs and photovoltatic devices would be enhanced if such devices could be operated with greater efficiency, such as by increasing the amount of light produced per unit of electrical energy expended in the case of OLEDs.

While impressive strides have been made in the enhancement of organic electro-optic device efficiency, further improvements are needed in order to provide devices which may be operated with greater economy.

### BRIEF DESCRIPTION

In one embodiment the invention provides an organic opto-electronic device comprising

(a) a cathode comprising at least one zero-valent metal;

(b) an anode; and

(c) an opto-electronically active organic material disposed between said cathode and said anode;

wherein said cathode is in contact with at least one organic ammonium salt.

In another embodiment the invention provides an organic opto-electronic device comprising

(a) a cathode comprising at least one zero-valent metal;

(b) an anode; and

(c) an opto-electronically active organic material disposed between said cathode and said anode;
wherein said cathode is in contact with at least one organic ammonium salt having structure (I) 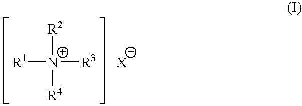
wherein R¹-R⁴ are independently at each occurrence a C₁-C₂₀ aliphatic radical, a C₃-C₂₀ cycloaliphatic radical, or a C₃-C₂₀ aromatic radical, and wherein X⁻ is selected from the group consisting of monovalent inorganic anions, monovalent organic anions, polyvalent inorganic anions, polyvalent organic anions, and mixtures thereof.

In another embodiment, the invention provides an OLED device comprising

(a) a cathode comprising at least one zero-valent metal;

(b) an anode;

(c) an opto-electronically active organic material disposed between said cathode and said anode; and

(d) at least one organic ammonium salt having structure (I) 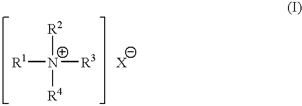
wherein R¹-R⁴ are independently at each occurrence a C₁-C₂₀ aliphatic radical, a C₃-C₂₀ cycloaliphatic radical, or a C₃-C₂₀ aromatic radical, and wherein X⁻ is selected from the group consisting of monovalent inorganic anions, monovalent organic anions, polyvalent inorganic anions, polyvalent organic anions, and mixtures thereof; said ammonium salt being disposed between the opto-electrtronically active organic material and the cathode, said ammonium salt being in contact with the cathode.

### BRIEF DESCRIPTION OF DRAWINGS

These and other features, aspects, and advantages of the present invention will become better understood when the following detailed description is read with reference to the accompanying drawings in which like characters represent like parts throughout the drawings, wherein:

FIG. 1 is a schematic representation of a first opto-electronic device structure comprising a cathode in contact with an organic ammonium salt in accordance with embodiments of the present invention;

FIG. 2 is a schematic representation of a second opto-electronic device structure comprising an organic ammonium salt and a charge injection material layer in accordance with embodiments of the present invention;

FIG. 3 is a schematic representation of a third optoelectronic device structure having a layer comprising an organic ammonium salt in accordance with embodiments of the present invention;

FIG. 4 shows the a plot of Efficiency versus Current Density for the OLED device of Comparative Example 1 (C.Ex.1) a device comprising a light emitting polymer (LEP) as the opto-electronically active material and an aluminum (Al) as the cathode;

FIG. 5 illustrates the I-V behavior of OLED device of Example 1 under forward and reverse bias;

FIG. 6 presents a plot of Efficiency as a function of Current Density of the OLED of Example 1; and

FIG. 7 shows a plot of Current versus Bias Voltage of an exemplary embodiment of the present invention measured under illumination and in the dark.

### DETAILED DESCRIPTION

The present invention may be understood more readily by reference to the following detailed description of preferred embodiments of the invention and the examples included therein. In the following specification and the claims which follow, reference will be made to a number of terms which shall be defined to have the following meanings:

The singular forms “a”, “an” and “the” include plural referents unless the context clearly dictates otherwise.

“Optional” or “optionally” means that the subsequently described event or circumstance may or may not occur, and that the description includes instances where the event occurs and instances where it does not.

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthraceneyl groups (n=3) and the like. The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆ aromatic radical comprising a nitro group, the nitro group being a functional group. Aromatic radicals include halogenated aromatic radicals such as 4-trifluoromethylphenyl, hexafluoroisopropylidenebis(4-phen-1-yloxy) (i.e., —OPhC(CF₃)₂PhO—), 4-chloromethylphen-1-yl, 3-trifluorovinyl-2-thienyl, 3-trichloromethylphen-1-yl (i.e., 3-CCl₃Ph-), 4-(3-bromoprop-1-yl)phen-1-yl (i.e., 4-BrCH₂CH₂CH₂Ph-), and the like. Further examples of aromatic radicals include 4-allyloxyphen-1-oxy, 4-aminophen-1-yl (i.e., 4-H₂NPh-), 3-aminocarbonylphen-1-yl (i.e., NH₂COPh-), 4-benzoylphen-1-yl, dicyanomethylidenebis(4-phen-1-yloxy) (i.e., —OPhC(CN)₂PhO—), 3-methylphen-1-yl, methylenebis(4-phen-1-yloxy) (i.e., —OPhCH₂PhO—), 2-ethylphen-1-yl, phenylethenyl, 3-formyl-2-thienyl, 2-hexyl-5-furanyl, hexamethylene-1,6-bis(4-phen-1-yloxy) (i.e., —OPh(CH₂)₆PhO—), 4-hydroxymethylphen-1-yl (i.e., 4-HOCH₂Ph-), 4-mercaptomethylphen-1-yl (i.e., 4-HSCH₂Ph-), 4-methylthiophen-1-yl (i.e., 4-CH₃SPh-), 3-methoxyphen-1-yl, 2-methoxycarbonylphen-1-yloxy (e.g., methyl salicyl), 2-nitromethylphen-1-yl (i.e., 2-NO₂CH₂Ph), 3-trimethylsilylphen-1-yl, 4-t -butyldimethylsilylphenl-1-yl, 4-vinylphen-1-yl, vinylidenebis(phenyl), and the like. The term “a C₃-C₁₀ aromatic radical” includes aromatic radicals containing at least three but no more than 10 carbon atoms. The aromatic radical 1-imidazolyl (C₃H₂N₂—) represents a C₃ aromatic radical. The benzyl radical (C₇H₇—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is an cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene-2,2-bis (cyclohex-4-yl) (i.e., —C₆H₁₀C(CF₃)₂C₆H₁₀—), 2-chloromethylcyclohex-1-yl, 3-difluoromethylenecyclohex-1-yl, 4-trichloromethylcyclohex-1-yloxy, 4-bromodichloromethylcyclohex-1-ylthio, 2-bromoethylcyclopent-1-yl, 2-bromopropylcyclohex-1-yloxy (e.g., CH₃CHBrCH₂C₆H₁₀—), and the like. Further examples of cycloaliphatic radicals include 4-allyloxycyclohex-1-yl, 4-aminocyclohex-1-yl (i.e., H₂NC₆H₁₀—), 4-aminocarbonylcyclopent-1-yl (i.e., NH₂COC₅H₈—), 4-acetyloxycyclohex-1-yl, 2,2-dicyanoisopropylidenebis(cyclohex-4-yloxy) (i.e., —OC₆H₁₀C(CN)₂C₆H₁₀O—), 3-methylcyclohex-1-yl, methylenebis(cyclohex-4-yloxy) (i.e., —OC₆H₁₀CH₂C₆H₁₀—), 1-ethylcyclobut-1-yl, cyclopropylethenyl, 3-formyl-2-terahydrofuranyl, 2-hexyl-5-tetrahydrofuranyl, hexamethylene-1,6-bis(cyclohex-4-yloxy) (i.e., —OC₆H₁₀(CH₂)₆C₆H₁₀O—), 4-hydroxymethylcyclohex-1-yl (i.e., 4-HOCH₂C₆H₁₀—), 4-mercaptomethylcyclohex-1-yl (i.e., 4-HSCH₂C₆H₁₀—), 4-methylthiocyclohex-1-yl (i.e., 4-CH₃SC₆H₁₀—), 4-methoxycyclohex-1-yl, 2-methoxycarbonylcyclohex-1-yloxy (2-CH₃OCOC₆H₁₀O—), 4-nitromethylcyclohex-1-yl (i.e., NO₂CH₂C₆H₁₀—), 3-trimethylsilylcyclohex-1-yl, 2-t -butyldimethylsilylcyclopent-1-yl, 4-trimethoxysilylethylcyclohex-1-yl (e.g., (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

As used herein the term “aliphatic radical” refers to an organic radical having a valence of at least one consisting of a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl,group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl, difluorovinylidene, trichloromethyl, bromodichloromethyl, bromoethyl, 2-bromotrimethylene (e.g., —CH₂CHBrCH₂—), and the like. Further examples of aliphatic radicals include allyl, aminocarbonyl (i.e., —CONH₂), carbonyl, 2,2-dicyanoisopropylidene (i.e., —CH₂C(CN)₂CH₂—), methyl (i.e., —CH₃), methylene (i.e., —CH₂—), ethyl, ethylene, formyl (i.e.,—CHO), hexyl, hexamethylene, hydroxymethyl (i.e.,—CH₂OH), mercaptomethyl (i.e., —CH₂SH), methylthio (i.e., —SCH₃), methylthiomethyl (i.e., —CH₂SCH₃), methoxy, methoxycarbonyl (i.e., CH₃OCO—), nitromethyl (i.e., —CH₂NO₂), thiocarbonyl, trimethylsilyl (i.e., (CH₃)₃Si—), t-butyldimethylsilyl, 3-trimethyoxysilypropyl (i.e., (CH₃O)₃SiCH₂CH₂CH₂—), vinyl, vinylidene, and the like. By way of further example, a C₁-C₁₀ aliphatic radical contains at least one but no more than 10 carbon atoms. A methyl group (i.e., CH₃—) is an example of a C₁ aliphatic radical. A decyl group (i.e., CH₃(CH₂)₉—) is an example of a C₁₀ aliphatic radical.

As noted the invention provides an organic opto-electronic device comprising a cathode comprising at least one zero-valent metal; an anode; and an opto-electronically active organic material disposed between said cathode and said anode; wherein said cathode is in contact with at least one organic ammonium salt. In one embodiment, the cathode is in contact with at least one organic ammonium salt having structure (I) 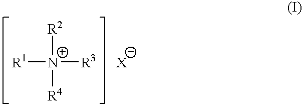
wherein R¹-R⁴ are independently at each occurrence a C₁-C₂₀ aliphatic radical, a C₃-C₂₀ cycloaliphatic radical, or a C₃-C₂₀ aromatic radical, and wherein X⁻ is selected from the group consisting of monovalent inorganic anions, monovalent organic anions, polyvalent inorganic anions, polyvalent organic anions, and mixtures thereof.

In one embodiment the cathode serves the purpose of injecting negative charge carriers (electrons) into the electro-active organic layer. In an embodiment, the cathode comprises metals, such as K, Li, Na, Cs, Mg, Ca, Sr, Ba, Al, Ag, Au, In, Sn, Zn, Zr, Sc, Y, elements of the lanthanide series, alloys thereof, or mixtures thereof. Suitable alloy materials for the manufacture of cathode layer are Ag—Mg, Al—Li, In—Mg, Al—Ca, and Al—Au alloys. Layered non-alloy structures are also feasible, such as a thin layer of a metal such as calcium, or a metal fluoride, such as LiF, covered by a thicker layer of a zero valent metal, such as aluminum or silver. In one embodiment, the cathode comprises a zero valent metal. In one embodiment, the cathode comprises a zero valent metal selected from the group consisting of aluminum, copper, zinc, silver, nickel, palladium, platinum, iridium, lithium, sodium, potassium, calcium, barium, strontium, and mixtures of two or more of the foregoing. The cathode may be deposited on the underlying element by physical vapor deposition, chemical vapor deposition, sputtering, or like technique. In one embodiment the cathode is transparent. The term “transparent” means allowing at least 50 percent, commonly at least 80 percent, and more commonly at least 90 percent, of light in the visible wavelength range to be transmitted through at an incident angle of less than or equal to 10 degrees. This means that a device or article, for example a transparent cathode, described as being “transparent” will transmit at least 50 percent of light in the visible range which impinges on the device or article at an incident angle of about 10 degrees or less.

The anode generally comprises a material having a bulk conductivity of at least 100 Siemens per centimeter, as measured by a four-point probe technique. Indium tin oxide (ITO) is typically used as the anode because it is substantially transparent to light transmission and thus facilitates light emitted from electro-active organic layer to escape through the ITO anode layer without being significantly attenuated. Other materials which may be utilized as the anode layer include tin oxide, indium oxide, zinc oxide, indium zinc oxide, zinc indium tin oxide, antimony oxide, and mixtures thereof. The cathode and the anode are referred to as “conductive layers”.

In fabricating the devices of the present invention the conductive layers may be deposited on the underlying element by physical vapor deposition, chemical vapor deposition, sputtering, or like processes, or a combination of two or more of the foregoing techniques may be employed. The thickness of each conductive layer may vary independently but is generally in the range from about 10 nanometers to about 500 nanometers. Thus in one embodiment the thicknesses of the conductive layers fall within a range from about 10 nanometers to about 500 nanometers in an embodiment, from about 10 nanometers to about 200 nanometers in another embodiment, and from about 50 nanometers to about 200 nanometers in still another embodiment. A thin, substantially transparent layer of a metal, for example, having a thickness of less than about 50 nanometers, can also be used as a suitable conductive layer. Suitable exemplary metals include silver, copper, tungsten, nickel, cobalt, iron, selenium, germanium, gold, platinum, aluminum, or mixtures of two or more of the foregoing, and metal alloys comprising one or more of the foregoing. In one embodiment, the anode is disposed on a substantially transparent substrate, such a glass substrate of a an organic polymeric substrate.

In one embodiment, the opto-electronically active material is disposed as a layer and serves as the transport medium for both holes and electrons in the opto-electronic device. In OLEDs, the holes and electrons in the opto-electronically active layer combine to form excited state species which emit EM radiation in the visible range. In certain embodiments, a reversal of the voltage bias used to transform electrical energy into light energy in an OLED, converts the OLED into a photovoltaic device which transforms light energy into electrical energy. In a photovoltaic device, holes and electrons are produced by the combined effect of light incident upon the opto-electronically active material, and the applied voltage bias. The holes and electrons so produced then result in a flow of electric current. Thus, the opto-electronic devices of the present invention are characterized by the ability to convert electrical energy into light energy (OLEDs), and upon reversal of the voltage bias, to convert light energy into electrical energy (photovoltaic devices (PVs)). Opto-electronically active organic materials are typically chosen to electroluminesce in the desired wavelength range.

As noted, the opto-electronically active material is typically disposed as an opto-electronically active layer within the opto-electronic device, said layer being disposed between the conductive layers of the device. The thickness of the opto-electronically active layer is typically from about in the exemplary range of about 10 nanometers to about 300 nanometers. The active opto-electronically active material used to form the opto-electronically active layer is an organic material which may be a polymer, a copolymer, a mixture of polymers or copolymers, or lower molecular-weight organic molecules having unsaturated bonds. Such materials generally possess a delocalized π-electron system, which typically enables the polymer chains or organic molecules to support positive and negative charge carriers with relatively high mobility. Suitable opto-electronically active polymers are illustrated by poly(n-vinylcarbazole) (“PVK”, emitting violet-to-blue light in a wavelength range of from about 380 to about 500 nanometers) and poly(n-vinylcarbazole) derivatives; polyfluorene and polyfluorene derivatives such as poly(alkylfluorene), for example poly(9,9-dihexylfluorene) (emitting light in a wavelength range of from about 410 to about 550 nanometers), poly(dioctylfluorene) (wavelength at peak electroluminescent (EL) emission of about 436 nanometers), and poly{9,9-bis(3,6-dioxaheptyl)-fluorene-2,7diyl} (emitting light in a wavelength range of from about 410 to about 550 nanometers); poly(paraphenylene) (“PPP”) and its derivatives such as poly(2-decyloxy-1,4-phenylene) (emitting light in a wavelength range of from about 400 to about 550 nanometers) and poly(2,5-diheptyl-1,4-phenylene); poly(p-phenylene vinylene) (“PPV”) and its derivatives such as dialkoxy-substituted PPV and cyano-substituted PPV; polythiophene and its derivatives such as poly(3-alkylthiophene), poly(4,4′-dialkyl-2,2′-bithiophene), and poly(2,5-thienylene vinylene); poly(pyridine vinylene) and its derivatives; polyquinoxaline and its derivatives; and polyquinoline and its derivatives. Mixtures of these polymers and/or copolymers comprising structural units common to two or more of the aforementioned polymers may be used to tune the color of emitted light in an organic opto-electronic device which is an OLED, for example.

Another class of suitable organic materials which may be employed as the opto-electronically active organic material are polysilanes. Typically, polysilanes are linear silicon-backbone polymers substituted with a variety of alkyl and/or aryl groups. Polysilanes are quasi one-dimensional materials with delocalized sigma-conjugated electrons along polymer backbone. Examples of suitable polysilanes include, but are not limited to, poly(di-n-butylsilane), poly(di-n-pentylsilane), poly(di-n-hexylsilane), poly(methylphenylsilane), and poly{bis(p-butylphenyl)silane}. The polysilanes generally emit light in a wavelength in a range from about 320 nanometers to about 420 nanometers.

In certain embodiments, organic materials having molecular weight less than about 5000 grams per mole and comprising one or more aromatic radicals also applicable as light emissive opto-electronically active organic materials. An example of such materials is 1,3,5-tris{N-(4-diphenylaminophenyl) phenylamino}benzene, which emits light in the wavelength range of from about 380 to about 500 nanometers. The light emissive organic layer also may comprise still lower molecular weight organic molecules, such as phenylanthracene, tetraarylethene, coumarin, rubrene, tetraphenylbutadiene, anthracene, perylene, coronene, their derivatives, or a combination of two or more of the foregoing. These materials generally emit light having maximum wavelength of about 520 nanometers. Still other advantageous materials are the low molecular-weight metal organic complexes such as aluminum-, gallium-, and indium-acetylacetonate, which emit light in a wavelength range of from about 415 to about 457 nanometers. Suitable aluminum compounds include aluminum (picolylmethylketone)-bis{2,6-di(t-butyl)phenoxide}. Scandium-(4-methoxy -picolylmethylketone)-bis(acetylacetonate), which emits in the wavelength range of from about 420 to about 433 nanometers may be employed. In certain embodiments, for example white light applications, beneficial light emissive organic materials are those that emit light in the blue-green wavelength range.

Other opto-electronically active organic materials that emit in the visible wavelength range and that may be employed with the present technique are organometallic complexes of 8-hydroxyquinoline, such as tris(8-quinolinolato)aluminum and other materials disclosed in U. Mitschke and P. Bauerle, “The Electroluminescence of Organic Materials,” J. Mater. Chem., Vol. 10, pp. 1471-1507 (2000), which is incorporated herein by reference. Additional exemplary organic materials that may be employed in the opto-electronically active layer of the present invention include those disclosed by Akcelrud in “Electroluminescent Polymers”, Progress in Polymer Science, Vol 28 (2003), pp. 875-962, which is also incorporated herein by reference. The opto-electronically active organic material used in the present invention may include polymeric materials whose structures comprise various combinations of structures or structural units that are known in the art to be, or expected to be, active, together with structures that are either known or are potentially expected to perform other functions that enhance device performance, such as hole transport, electron transport, charge transport, and charge confinement, and so forth.

In one embodiment, the organic opto-electronic device provided by the present invention comprises a plurality of layers comprising the opto-electronically active organic material, said layers comprising the same or different opto-electronically active organic materials. In one embodiment, the present invention provides a organic opto-electronic device comprising a plurality of electro-active layers each comprising the opto-electronically active organic material wherein said layers are formed by successively depositing, one layer comprising an opto-electronically active organic material on top of another layer comprising an opto-electronically active organic material. In one embodiment, each layer comprises a different opto-electronically active organic material that emits light in a different wavelength range. In an alternate embodiment of the present invention, each layer comprises a mixture of two or more opto-electronically active organic materials. In one embodiment, the organic opto-electronic device is an OLED comprising a plurality of electro-active layers, each of said layers comprising a different light emissive organic material, each of said different light emissive organic materials emitting light in a different wavelength range.

In the various embodiments of the present invention, the cathode is in contact with an organic ammonium salt, which in certain embodiments is an organic ammonium salt having structure (I) 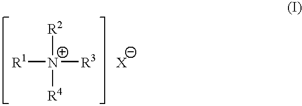
wherein R¹-R⁴ are independently at each occurrence a C₁-C₂₀ aliphatic radical, a C₃-C₂₀ cycloaliphatic radical, or a C₃-C₂₀ aromatic radical, and wherein X⁻ is selected from the group consisting of monovalent inorganic anions, monovalent organic anions, polyvalent inorganic anions, polyvalent organic anions, and mixtures thereof.

In one embodiment, R¹, R², R³ and R⁴ in the ammonium salt represented by the structure (I) are the same or different and each represents a hydrocarbon group having 1 to 20 carbon atoms, wherein R¹, R 2, R³ and R⁴ are at any occurrence independently selected from the group consisting of aliphatic and aromatic hydrocarbon groups. For example, R¹, R², R³ and R⁴ may be methyl, ethyl, n-propyl, isopropyl, allyl, n-butyl, sec-butyl, tert-butyl, 2-butenyl, 1-pentyl, 2-pentyl, 3-pentyl, 2-methyl-1-butyl, isopentyl, tert-pentyl, 3-methyl-2-butyl, neopentyl, n-hexyl, 4-methyl-2-pentyl, cyclopentyl, cyclohexyl, 1-heptyl, 3-heptyl, 1-octyl, 2-octyl, 2-ethyl-1-hexyl, 1,1-dimethyl-3,3-dimethylbutyl (popular name: tert-octyl), nonyl, decyl, phenyl, 4-toluyl, benzyl, 1-phenylethyl, and 2-phenylethyl. In one embodiment R¹, R², R³ and R⁴ are aliphatic hydrocarbon groups having from 1 to 12 carbon atoms, such as methyl, ethyl, n-propyl, isopropyl, tert-butyl, tert-pentyl and 1,1-dimethyl-3,3-dimethylbutyl.

In an alternate embodiment R¹, R², R³ and R⁴ may form a cyclic structure comprising at least one heteroatom. For example in the case wherein both R¹ and R² are bound to the same nitrogen atom and both R¹ and R² represent aliphatic radicals, R¹ and R² may together form a cyclic structure comprising at least one heteroatom atom.

The anionic species X⁻ of structure I is selected from the group consisting of monovalent inorganic anions, monovalent organic anions, polyvalent inorganic anions, polyvalent organic anions, and mixtures thereof. Monovalent inorganic anions include chloride, bromide, fluoride, methanesulfonate, hydrogensulfate, bicarbonate, and the like. Polyvalent inorganic anions include carbonate, sulfate, sulfite, and the like. Monovalent organic anions include methanesulfonate, acetate, alkoxide, acetylacetonate, and the like. Polyvalent organic anions include malonate, succinate, ethylenedisufonate (i.e. —O₃SCH₂CH₂SO₃—), and the like.

A wide variety of organic ammonium salts may be employed as components of the organic opto-electronic devices of the present invention. Organic ammonium salts which may be employed, include ammonium salts having structure (I) which are exemplified in Table 1. (The dashed line (------) signals the point of attachment of the group). Those skilled in the art will understand that structure (I) is not intended to exemplify all suitable organic ammonium salts which may be employed in the present invention. For example, the imidazolium salts 1-ethyl-3-methylimidazolium bis(trifluoromethylsulfonyl)imide and 1-ethyl-3-methylimidazolium hexafluorophosphate fall outside the genus defined by structure (I) and yet may be employed as organic ammonium salts in the practice of the present invention. Moreover, those skilled in the art will appreciate that mixtures of organic ammonium salts may be employed advantageously in the practice of the present invention. Those skilled in the art will further understand that the performance characteristics of the organic opto-electronic devices of the present invention may be adjusted by changing the structure and/or physical properties of the organic ammonium salt employed. In one embodiment, the organic ammonium salt is an ammonium salt which is an ionic liquid. In an alternate embodiment, a mixture comprising at least two organic ammonium salts is employed. The organic ammonium salt employed may be used in essentially pure form or as a mixture comprising an organic ammonium salt and one or more adjuvants. Suitable adjuvants include solvents, oils, waxes, and the like.

TABLE 1
Illustrative Organic Ammonium Salts

| | | | | | (I) |
|---|---|---|---|---|---|
| 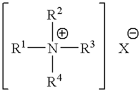 | | | | | |
| Entry | R¹ | R² | R³ | R⁴ | X^{⊖} |
| I-1 | Me | Me | Me | Me | Cl^{⊖} |
| I-2 | Ph | Ph | Ph | Ph | AcO^{⊖} |
| I-3 | Me | Me | Me | 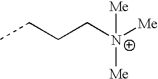 | 2 Br^{⊖} |
| I-4 | Ph | Ph | Ph | 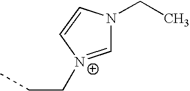 | 2 Br^{⊖} |
| I-5 | Me | Me | Me | 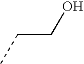 | I^{⊖} |
| I-6 (zwitter ionic ammonium salt) | Ph | Ph | Ph | 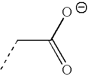 | — |
| I-7 | Et | Et | Et | 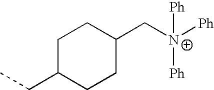 | 3 Br^{⊖} |
| I-8 | Ph | Ph | Ph | 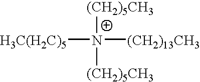 | 2 F^{⊖} |

In one embodiment the organic ammonium salt is selected from the group consisting of trihexyltetradecylammonium bis(trifluoromethylsulfonyl)amide, trihexyl(tetradecyl)ammonium hexafluorophosphate, trihexyl(tetradecyl)ammonium dicyanamide, methyltriisobutylammonium tosylate, tetradecyltrihexylammonium decanoate, tetradecyltrihexylammonium bis(2,4,4-trimethylpentyl)phosphinate, tetradecyltrihexylammonium bromide, tetrahexylammonium tetrafluoroborate, 1-ethyl-3-methylimidazolium bis(trifluoromethylsulfonyl)imide, 1-ethyl-3-methylimidazolium hexafluorophosphate, and mixtures thereof.

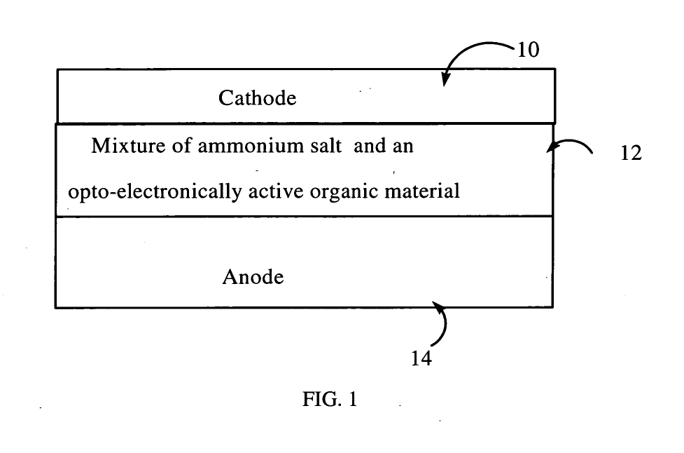

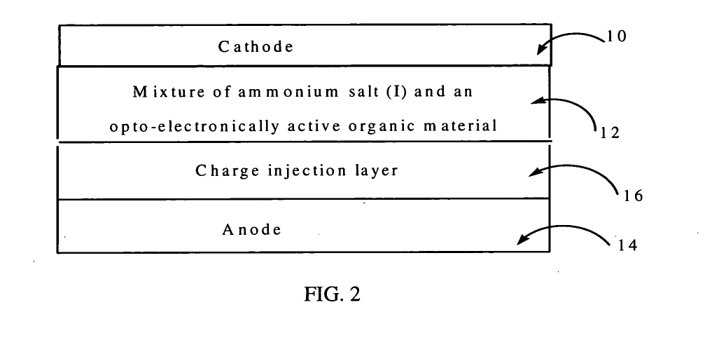

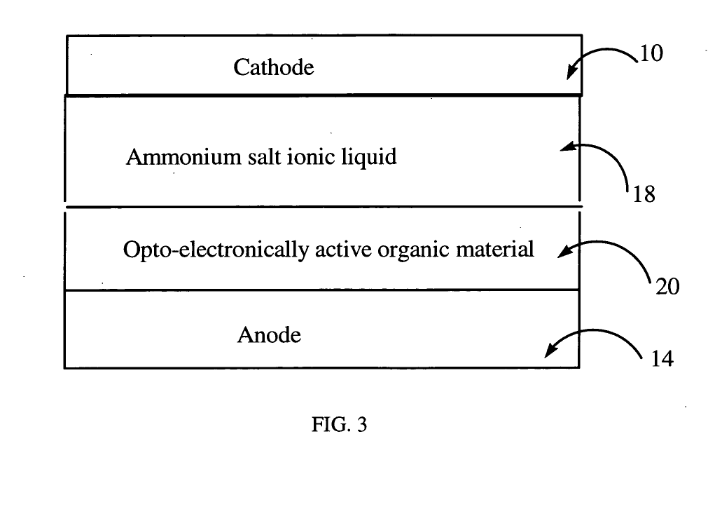

FIGS. 1-3 illustrate embodiments of the invention. In FIG. 1, an exemplary opto-electronic device is shown in which the organic ammonium salt is dispersed in an opto-electronically active organic material which emits light under the influence of a voltage bias applied across cathode 10 and anode 14. The combination of the ammonium salt and the opto-electronically active organic material is shown in FIG. 1 as layer 12. The organic ammonium salt is in contact with the anode by virtue of its being dispersed in the opto-electronically active organic material, there being no intervening layer between the cathode and the opto-electronically active organic material. FIG. 2 illustrates another embodiment of the present invention wherein the opto-electronic device comprises a cathode 10 in contact with a layer 12 comprising a mixture of an ammonium salt having structure (I) dispersed in an opto-electronically active organic material. The opto-electronic device shown in FIG. 2 also comprises an anode 14 and a charge injection layer 16. FIG. 3 illustrates yet another embodiment of the present invention in which the cathode 10 is in direct contact with a layer 18 of an ionic liquid comprising an ammonium salt having structure (I). The layer of the ionic liquid 18 serves as an intervening layer between a layer 20 comprising an opto-electronically active organic material, which in one embodiment, is a mixture of two or more electro-active polymers. The organic opto-electronic device of FIG. 3 may be operated as an OLED by applying a voltage bias across cathode 10 and anode 14. The organic opto-electronic device of FIG. 3 may be operated as a photovoltaic (PV) device by applying a reverse (relative to the voltage bias employed when the opto-electronic device is operated as an OLED) voltage bias across cathode 10 and anode 14.

One or more layers disposed between the conductive layers, in addition to the layer comprising the opto-electronic material, may also be present in the organic opto-electronic device provided by the present invention. Such layers are at times referred to as “intervening layers” since they are typically located between the layer comprising the opto-electronic material and one or more of the conductive layers. For example, in FIG. 3 comprises an intervening layer 16 between the anode 14 and the layer 12 comprising the opto-electronically active organic material. Various intervening layers may be included in the opto-electronic device to further increase the efficiency of the exemplary opto-electronic device. For example, an intervening layer can serve to improve the injection and/or transport of positive charges (holes) into the opto-electronic device. The thickness of each of these layers is typically kept below 500 nanometers, commonly below 100 nanometers. Exemplary materials for these intervening layers are in certain embodiments of low-to-intermediate molecular weight (for example, less than about 2000 grams per mole) organic molecules, poly(3,4-ethylenedioxythipohene) doped with polystyrenesulfonic acid (“PEDOT:PSS”), and polyaniline, to name a few. They may be applied during the manufacture of the device by conventional methods such as spray coating, dip coating, or physical or chemical vapor deposition, and other processes. In one embodiment of the present invention, a hole injection enhancement layer is introduced between the anode layer and the active organic material layer to provide a higher injected current at a given forward bias and/or a higher maximum current before the failure of the device. Thus, the hole injection enhancement layer facilitates the injection of holes from the anode. Exemplary materials for the hole injection enhancement layer are arylene-based compounds, such as those disclosed in U.S. Pat. No. 5,998,803, which is incorporated herein by reference. Particular examples include 3,4,9,10-perylenetetra-carboxylic dianhydride and bis(1,2,5-thiadiazolo)-p -quinobis(1,3-dithiole).

In one embodiment, the exemplary device includes an intervening layer which is a hole transport layer. In one embodiment, the hole transport layer is disposed between a hole injection enhancement layer and the layer comprising the layer comprising the opto-electronically active organic material. The hole transport layer transports holes and blocks the transportation of electrons so that holes and electrons may be substantially optimally combined in the active organic material layer. Exemplary materials for the hole transport layer may include triarylamines, triaryldiamines, tetraphenyldiamine, aromatic tertiary amines, hydrazone derivatives, carbazole derivatives, triazole derivatives, imidazole derivatives, oxadiazole derivatives having an amino group, and polythiophenes, to name a few.

In other embodiments, an intervening layer includes an “electron injecting and transporting enhancement layer” as an additional layer, which is typically disposed between an electron-donating material and the opto-electronically active organic material layer. Typical materials utilized for the electron injecting and transporting enhancement layer may include metal organic complexes, such as tris(8-quinolinolato)aluminum, oxadiazole derivatives, perylene derivatives, pyridine derivatives, pyrimidine derivatives, quinoline derivatives, quinoxaline derivatives, diphenylquinone derivatives, and nitro-substituted fluorene derivatives, and the like.

In an embodiment, the opto-electronically active material may also be co-mingled with a polymeric material that can serve as a matrix polymer. Generally, any of the known polymeric materials may be used.

In one embodiment, the layer comprising the opto-electronically active material further includes a fluorescent dye or a phosphorescent dye. In one embodiment, the present invention provides an organic opto-electronic device which is an organic light emitting diode (OLED), said OLED comprising a photoluminescent (“PL”) layer. In one embodiment, the photoluminescent layer is a fluorescent layer comprising at least one fluorescent material. In an alternate embodiment of the present invention the photoluminescent layer is a phosphorescent layer comprising at least one phosphorescent material. In one embodiment, the opto-electronic device provided by the present invention comprises both a fluorescent layer and phosphorescent layer. Suitable photoluminescent materials for use in such layers are, for example those disclosed in U.S. Pat. No. 6,847,162.

The opto-electronic devices provided by the present invention generally include a cathode comprising at least one zero-valent metal, said cathode being in contact with an organic ammonium salt having structure (I), an anode, an intervening layer and an opto-electronically active organic material layer. In an embodiment, at least one of the cathode or the anode layers is transparent. In another embodiment, all the layers present in the opto-electronic devices are transparent as defined herein. In one embodiment, the opto-electronic device provided by the present invention comprises a transparent electrode which exhibits a percent light transmission of greater than or equal to about 90 percent in an embodiment, and greater than or equal to 95 percent in another embodiment. In one embodiment, the present invention provides an opto-electronic device which is a photovoltaic (“PV”) cell which exhibits efficient transport of electrons across an interface between an transparent electrode and an adjacent active organic material.

In another aspect, the present invention encompasses a method for operating an opto-electronic device. The method includes applying an electrical field or light energy to the opto-electronic device to convert between electrical energy and light energy. In yet another embodiment the opto-electronic devices, may be an organic photovoltaic device, a photodetector, a display device, and an organic light emitting device. Display devices are exemplified by devices used for signage. In one embodiment the device can be operable in a direct current mode. Alternatively the device can be operable in an alternating current mode.

### EXAMPLES

### General Procedure

In the following examples, poly(3,4-ethylenedioxythiophene) doped with polystyrene sulfonate (PEDOT:PSS) was purchased from Bayer Corporation under the trade name Baytron® P. A green light-emitting polymer (LEP) was obtained commercially from Dow Chemical Company under the trade name of Lumation® 1304. Devices were made as follows. Pre-patterned ITO coated glass used as the anode substrate was cleaned with UV-ozone for 10 minutes. Then a layer (60 nm) of {poly(3,4)-ethylendioxythiophene/polystyrene sulfonate} (PEDOT:PSS) polymer was deposited atop the ITO via spin-coating and the assembly was baked for about 1 hour at 180° C. in air. The light emitting layer comprised a mixture of the light emitting polymer Lumation 1304 and an ammonium salt ionic liquid. In Comparative Example 1, no ammonium salt ionic liquid was included in the light emitting layer. The light emitting layer was formed by spin coating a solution of the LEP and the ammonium salt ionic liquid on top of the PEDOT:PSS layer. Then the samples were transferred into a glovebox filled with Argon (moisture and oxygen was nominally less than 1 ppm and 10 ppm, respectively). A 110 nm Al cathode layer was then thermally-evaporated atop of the light emitting layer. After metallization, the devices were encapsulated with a cover glass sealed with an optical adhesive NORLAND 68 obtained from Norland products, Inc, Cranbury, N.J. 08512, USA. The active area was about 0.2 cm².

TABLE 2
Ammonium Salt Ionic Liquid Employed In Examples 1 and 2
Ionic Liquid

| Cation | Anion |
|---|---|
| 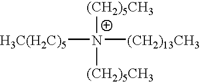 | ^{⊖}BF₄ |

### Comparative Example 1

An OLED was prepared as described in the General Procedure. The OLED was identical to the OLEDS of Examples 1 and 2 with the exception that no ammonium salt was included in the light emitting layer.

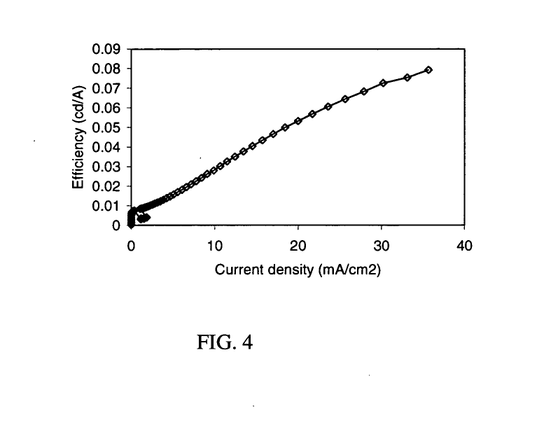

The performance of the OLEDs of Examples 1 and 2 and of Comparative Example 1 was evaluated by measuring the current-voltage-luminance (I-V-L) characteristics of each OLED. A photodiode calibrated with a luminance meter (Minolta LS-110) was used to measure the luminance (in units of candela per square meter, cd/m2). A plot of efficiency (measured in candela per ampere, cd/A) as a function of current density (measured in milliamperes per square centimeter, mA/cm2) was obtained for each device from its I-V-L data. FIG. 4 shows the a plot of Efficiency versus Current Density for the OLED device of Comparative Example 1 (C.Ex.1) a device comprising a light emitting polymer (LEP) as the opto-electronically active material and an aluminum (Al) as the cathode.

### Example 1 (Ex.1)

An exemplary OLED was fabricated as described in the General Procedure. The ammonium salt employed was an ionic liquid trihexyltetradecylammonium tetrafluoroborate {CH₃(CH₂)₅}₄N(BF₄) (CAS# 15553-50-1), obtained from Sigma-Aldrich. The solution of LEP and the ionic liquid was prepared by mixing 2 milliliters of a 1.0 wt % solution of the LEP in tetrahydrofuran and 0.20 milliliters of a 0.5% solution of trihexyltetradecylammonium tetrafluoroborate in tetrahydrofuran.

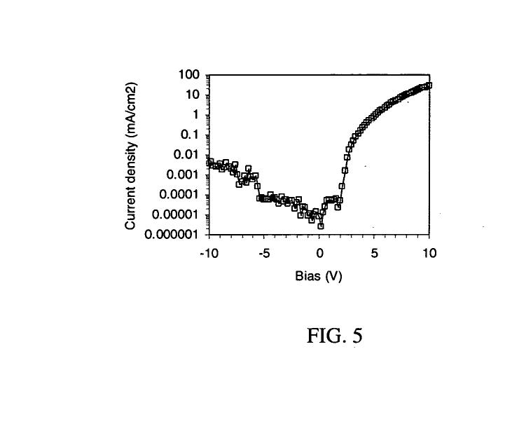

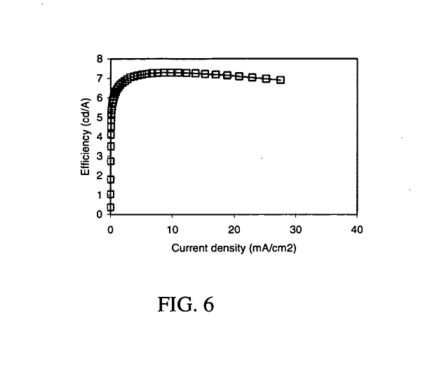

Examination of FIGS. 5 and 6 clearly shows that the OLED comprising the ammonium salt ionic liquid functions as an organic light-emitting diode, as evidenced by the highly asymmetric I-V curve (FIG. 5), i.e. the current under forward bias is more than 4 orders of magnitude greater than the current under reverse bias. In I-V measurement shown in FIG. 5, the bias voltage was ramped from −10 to 10 Volts with a step of 0.2V. FIG. 6 showing a plot of Efficiency versus Current Density, shows that the efficiency of the exemplary OLED of Example 1 is superior to the efficiency observed for Comparative Example 1 (Compare FIGS. 4 and 6).

### Example 2

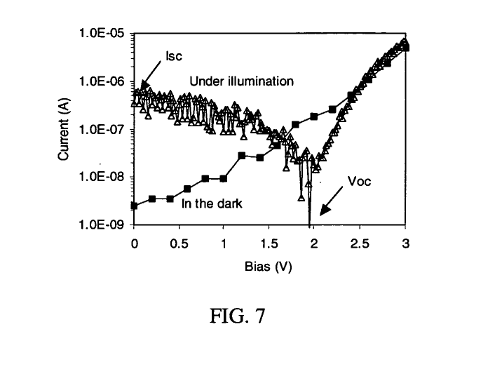

An exemplary organic opto-electronic device that could be used both as an OLED and a photovoltaic device (for example, a photodetector) was fabricated as in EXAMPLE 1. The ammonium salt used was an ionic liquid trihexyltetradecylammonium tetrafluoroborate. FIG. 7 shows I-V characteristics of the device of Example 2 under UV illumination and in the dark. Where the device was operated as a photovoltaic device, a hand-held long-wavelength UV-lamp having an intensity of about 3 mW/cm² at 364 nm was used as the illumination light source. The device was illuminated through the transparent ITO electrode.

As it can be seen in FIG. 7, the exemplary device exhibits a short-circuit current (Isc) of about 2×10⁻⁶ Amperes (corresponding to about 1×10⁻⁵ mA/cm²), which is more than two orders of magnitude higher than the current measured in the dark, at an open circuit voltage of 2.05V. The photo-responses observed clearly indicate that the exemplary device can be used as a photovoltaic device. In FIG. 7 the current was plotted against the applied voltage bias under illumination and in the dark. In FIG. 7 “Isc” (“short circuit current”) refers to the current at zero voltage bias measured under illumination and “Voc” (“open circuit voltage”) refers to the corresponding voltage when the current reaches its minimum.

The foregoing examples are merely illustrative, serving to illustrate only some of the features of the invention. The appended claims are intended to claim the invention as broadly as it has been conceived and the examples herein presented are illustrative of selected embodiments from a manifold of all possible embodiments. Accordingly, it is Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of.” Where necessary, ranges have been supplied, those ranges are inclusive of all sub-ranges there between. It is to be expected that variations in these ranges will suggest themselves to a practitioner having ordinary skill in the art and where not already dedicated to the public, those variations should where possible be construed to be covered by the appended claims. It is also anticipated that advances in science and technology will make equivalents and substitutions possible that are not now contemplated by reason of the imprecision of language and these variations should also be construed where possible to be covered by the appended claims.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An organic opto-electronic device comprising
a cathode comprising at least one zero-valent metal;
an anode; and
an opto-electronically active organic material disposed between said cathode and said anode;
wherein said cathode is in contact with at least one organic ammonium salt.

2. The device according to claim 1, wherein said ammonium salt has structure (I) 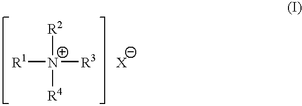
wherein R¹-R⁴ are independently at each occurrence a C₁-C₂₀ aliphatic radical, a C₃-C₂₀ cycloaliphatic radical, or a C₃-C₂₀ aromatic radical and wherein X⁻ is selected from the group consisting of monovalent inorganic anions, monovalent organic anions, polyvalent inorganic anions, polyvalent organic anions, and mixtures thereof.

3. The device according to claim 1, wherein said opto-electronically active organic material is in contact with said organic ammonium salt.

4. The device according to claim 1, which is an organic light-emitting diode.

5. The device according to claim 1, which is an organic photovoltaic device.

6. The device according to claim 1, which is operable in a direct current mode.

7. The device according to claim 1, which is operable in an alterating current mode.

8. The device according to claim 1, wherein said zero-valent metal is selected from the group consisting of aluminum, copper, zinc, silver, nickel, palladium, platinum, iridium, lithium, sodium, postassium, calcium, strontium, and mixtures of two or more of the foregoing.

9. The device according to claim 1, wherein said zero-valent metal comprises aluminum.

10. The device according to claim 1, wherein said cathode is transparent.

11. The device according to claim 1, wherein said anode comprises at least one material selected from the group consisting of indium-tin-oxide, tin oxide, indium oxide, zinc oxide, indium zinc oxide, zinc indium tin oxide, antimony oxide, and mixtures thereof.

12. The device according to claim 1, wherein said opto-electronically active organic material comprises at least one material selected from the group consisting of poly(n-vinylcarbazole), derivatives poly(n-vinylcarbazole); polyfluorene, derivatives of polyfluorene; poly(paraphenylene), and derivatives of poly(paraphenylene); poly(p-phenylene vinylene), derivatives of poly(p-phenylene vinylene); polythiophene, derivatives of polythiophene, and mixtures thereof.

13. The device according to claim 1, wherein said ammonium salt is selected from the group consisting of trihexyltetradecylammonium bis(trifluoromethylsulfonyl)amide, trihexyl(tetradecyl)ammonium hexafluorophosphate, trihexyl(tetradecyl)ammonium dicyanamide, methyltriisobutylammonium tosylate, tetradecyltrihexylammonium decanoate, tetradecyltrihexylammonium bis(2,4,4-trimethylpentyl)phosphinate, tetradecyltrihexylammonium bromide, tetrahexylammonium tetrafluoroborate, 1-ethyl-3-methylimidazolium bis(trifluoromethylsulfonyl)imide, 1-ethyl-3-methylimidazolium hexafluorophosphate, and mixtures thereof.

14. The device according to claim 2, wherein the at least one organic ammonium salt having structure (I) consists essentially of tetrahexylammonium tetrafluoroborate.

15. The device acoording to claim 1, wherein said ammonium salt is an ionic liquid.

16. The device according to claim 1, wherein the at least one organic ammonium salt is disposed upon the surface of said cathode.

17. The device according to claim 1, wherein the at least one organic ammonium salt is disposed within the opto-electronically active organic material.

18. The device according to claim 1, further comprising an intervening layer.

19. The device according to claim 18, wherein said intervening layer is selected from the group consisting of a hole injection layer, an electron blocking layer, a hole blocking layer, and an electron injection layer.

20. The device according to claim 1, wherein the at least one organic ammonium salt is disposed within at least one intervening layer.

21. An organic light-emitting diode comprising
a cathode comprising at least one zero-valent metal;
an anode;
an opto-electrtronically active organic material disposed between said cathode and said anode; and
at least one organic ammonium salt having structure (I) 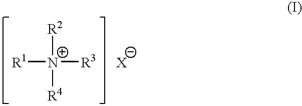
wherein R¹-R⁴ are independently at each occurrence a C₁-C₂₀ aliphatic radical, a C₃-C₂₀ cycloaliphatic radical, or a C₃-C₂₀ aromatic radical and wherein X⁻ is selected from the group consisting of monovalent inorganic anions, monovalent organic anions, polyvalent inorganic anions, polyvalent organic anions, and mixtures thereof;
said ammonium salt being disposed between the opto-electrtronically active organic material and the cathode, said ammonium salt being in contact with the cathode.

22. The device according to claim 21, wherein the at least one organic ammonium salt is disposed within the opto-electronically active organic material.

23. The device according to claim 21, further comprising an intervening layer.

24. The device according to claim 23, wherein said intervening layer is at least one selected from the group consisting of hole injection layer, an electron blocking layer, a hole blocking layer, and an electron injection layer.

25. The device according to claim 23, wherein the at least one organic ammonium salt is disposed within the at least one intervening layer.

26. An organic light-emitting diode device comprising
a cathode comprising zero-valent aluminum;
an anode comprising indium tin oxide;
an opto-electronically active polyfluorene between said cathode and said anode; and
at least one organic ammonium salt;
said ammonium salt being disposed between the opto-electrtronically active organic material and the cathode, said ammonium salt being in contact with the cathode.
